(19) United States
(12) Patent Application Publication
(10) Pub. No.: US 2026/0371579 A1
(43) Pub. Date: Nov. 19, 2026

(54) SEMICONDUCTOR STRUCTURE AND METHOD FOR FORMING THE SAME

(71) Applicant: Fujian Jinhua Integrated Circuit Co., Ltd., Quanzhou City (CN)

(72) Inventor: Daochu Wu, Quanzhou City (CN)

(73) Assignee: Fujian Jinhua Integrated Circuit Co., Ltd., Quanzhou City (CN)

(21) Appl. No.: 19/678,171

(22) Filed: May 15, 2026

(30) Foreign Application Priority Data
May 16, 2025 (CN) 202510637653.9

(51) Int. Cl. H10B 12/00

(52) U.S. Cl. CPC H10B 12/50; H10B 12/09

(57) ABSTRACT

A semiconductor structure includes a pad array and a first boundary pad surrounding the pad array. The pad array includes a plurality of storage node pads arranged along a first direction and a second direction. The first boundary pad includes a plurality of triangular protrusions that are arranged continuously along a third direction and disposed on a first side of the pad array. Each of the triangular protrusions has a vertex point and a first inclined edge and a second inclined edge that join at the vertex point. The second inclined edge comprises a concave profile. The stacked capacitor dynamic random access memory manufactured using the semiconductor structure of this invention may improve problems of capacitor peeling or collapse, and have enhanced device reliability.

### CROSS REFERENCE TO RELATED APPLICATION

This application claims the benefit of Chinese Patent Application No. 202510637653.9 filed on May 16, 2025, which is incorporated herein by reference.

### BACKGROUND OF THE INVENTION

### 1. Field of the Invention

The present invention generally relates to a semiconductor structure and a method for forming the same, and more particularly to a semiconductor structure including a pad array and a boundary pad and a method for forming the same.

### 2. Description of the Prior Art

A dynamic random access memory (DRAM) is a kind of volatile memory, which includes a cell region consisting of a plurality of memory cells and a peripheral region consisting of a control circuit. Each memory cell includes a transistor and a capacitor electrically connected to the transistor, and the transistor controls storage or release of charges into or from the capacitor to achieve the purpose of data storage. The control circuit can address each memory cell through word lines (WL) and bit lines (BL), which are distributed all over the cell region and are electrically connected to the memory cells, thereby controlling data access to the memory cells.

In order to obtain enhanced chip density, the structure of the memory cells has been developed towards a three-dimensional configuration, e.g., buried word lines and stacked capacitors. According to the technology of stacked capacitors, capacitors of the memory cells are disposed above the substrate and electrically connected to the transistors in the substrate in a vertical direction through plug structures and connection pad structures, thereby saving the substrate area occupied by the capacitors. In addition, it is easy to increase capacitance by increasing height of an electrode plate of the capacitor. However, there are still some technical problems that need further improvement, such as the peeling or collapse of capacitor structures in the peripheral region.

### SUMMARY OF THE INVENTION

An object of an embodiment of the present invention is to provide a semiconductor structure and a manufacturing method thereof, wherein the design of the boundary pad and the adjacent pad array may improve problems such as peeling or collapse of capacitor structures in the peripheral region, thereby enhancing the reliability of the device formed from the semiconductor structure.

One embodiment of the present invention provides a semiconductor structure having a pad array and a first boundary pad. The pad array includes a plurality of storage node pads arranged along a first direction and a second direction. The first boundary pad includes a plurality of triangular protrusions that are arranged continuously along a third direction and disposed on a first side of the pad array, wherein each of the triangular protrusions has a vertex point and a first inclined edge and a second inclined edge that join at the vertex point, wherein the second inclined edge comprises a concave profile.

One embodiment of the present invention provides a method for forming a semiconductor structure. The method includes the following steps: forming a conductive material layer, a first mask layer and a second mask layer successively on a substrate, performing a first self-aligned double patterning process to form a plurality of first ring-shaped trenches in the second mask layer thereby defining a plurality of line patterns that extend along a first direction and are parallel to each other, and performing a second self-aligned double patterning process to form a plurality of second ring-shaped trenches in the second mask layer, wherein the second ring-shaped trenches extend along a second direction and intersect the line patterns, resulting in a pad array pattern and a peripheral pattern surrounding the pad array, wherein the peripheral pattern includes a first peripheral pattern disposed on a first side of the pad array pattern, wherein the first peripheral pattern comprises a plurality of triangular protrusions arranged continuously along a third direction, wherein each of the triangular protrusions has a vertex point and a first inclined edge and a second inclined edge that join at the vertex point, wherein the second inclined edge comprises a concave profile.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

The accompanying drawings are directed to provide a better understanding of the embodiments and are included as parts of the specification of the present disclosure. These drawings and descriptions are used to illustrate the principles of the embodiments. It should be noted that all drawings are schematic, and the relative dimensions and scales have been adjusted for the convenience of drawing. Identical or similar features in different embodiments are marked with identical symbols.

FIG. 1 to FIG. 8 are schematic drawings illustrating intermediates of a semiconductor structure in a manufacturing process, according to an embodiment of the present invention, wherein:

FIG. 1 to FIG. 5 are plan views of the semiconductor structure;

FIG. 6 is a cross-sectional view of the semiconductor structure along line AA as illustrated in FIG. 1;

FIG. 7 is a is a cross-sectional view of the semiconductor structure along line AA as illustrated in FIG. 3; and

FIG. 8 is a cross-sectional view of the semiconductor structure along line AA as illustrated in FIG. 5.

FIG. 9 is a schematic drawing illustrating a plan view of a semiconductor structure according to an embodiment of the present invention.

FIG. 10 is a schematic drawing illustrating a plan view of a semiconductor structure according to an embodiment of the present invention.

### DETAILED DESCRIPTION

In the following description, preferred embodiments are presented in detail, accompanied by drawings, to assist those skilled in the art in better understanding the technical features and effects of this invention. In addition, the technical features in different embodiments may be replaced, recombined, or mixed with one another to constitute another embodiment without departing from the spirit of the present disclosure.

To enhance understanding and simplify the drawing, several drawings depict only a portion of the semiconductor structure, and the specific components in the drawing are not drawn to scale. Additionally, the numbers and dimensions of the components in the drawings are for illustrative purposes only and should not be regarded as limitations on the scope of this invention. Some components of the semiconductor structure may be omitted and not shown in the drawings. It is understood by those skilled in the art that terms such as “on”, “above”, “below”, “upper”, “lower”, “over”, “under”, etc. are used to indicate the relative positions of the components, and all the components may be oriented differently while still presenting the same structure. Both configurations are within the scope of this invention.

To enhance clarity in the description, spatial reference directions are defined in the drawings, including the first direction D1, the second direction D2, the third direction D3 and the fourth direction D4. The first direction D1, the second direction D2, the third direction D3 and the fourth direction D4 are parallel to a surface of the substrate 100. The third direction D3 and the fourth direction D4 are perpendicular to each other. The first direction D1 and the second direction D2 respectively have an angle between 15 degrees and 75 degrees with the third direction D3, but are not limited thereto. The angle between the first direction D1 and the second direction D2 varies from 30 degrees to 90 degrees, but is not limited thereto.

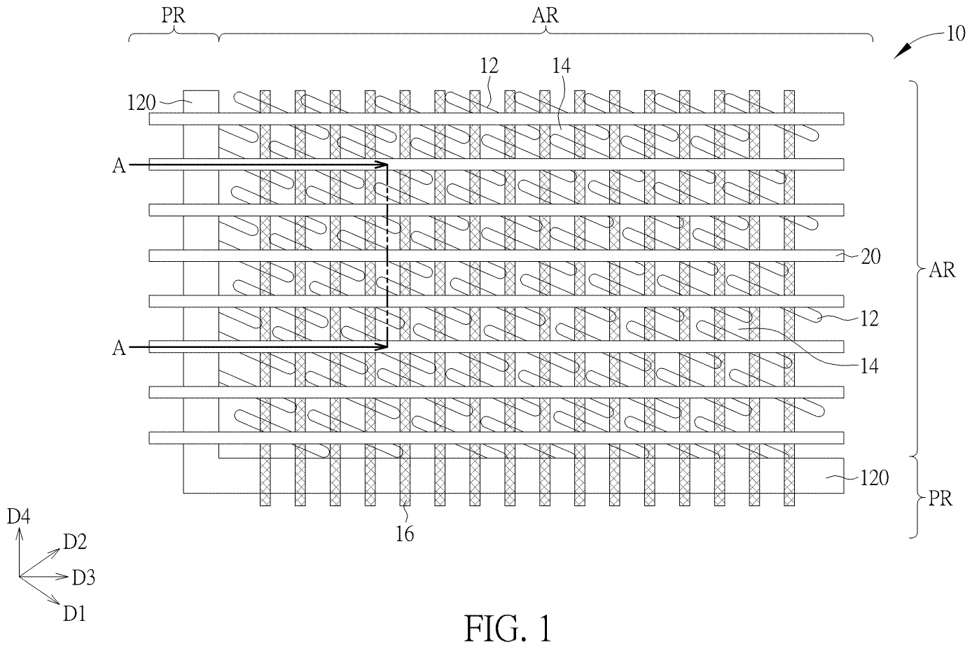

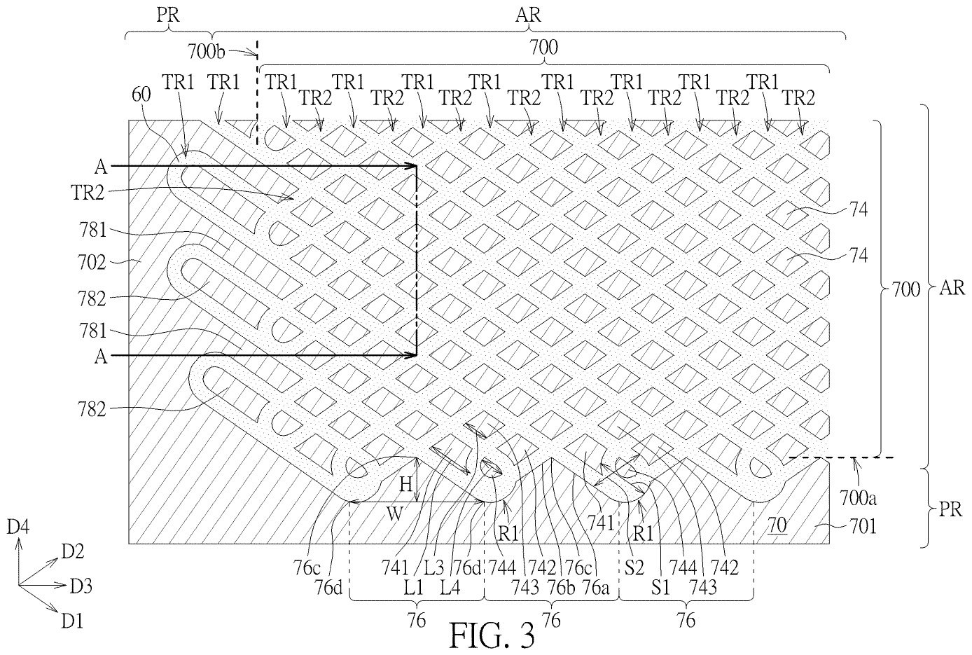

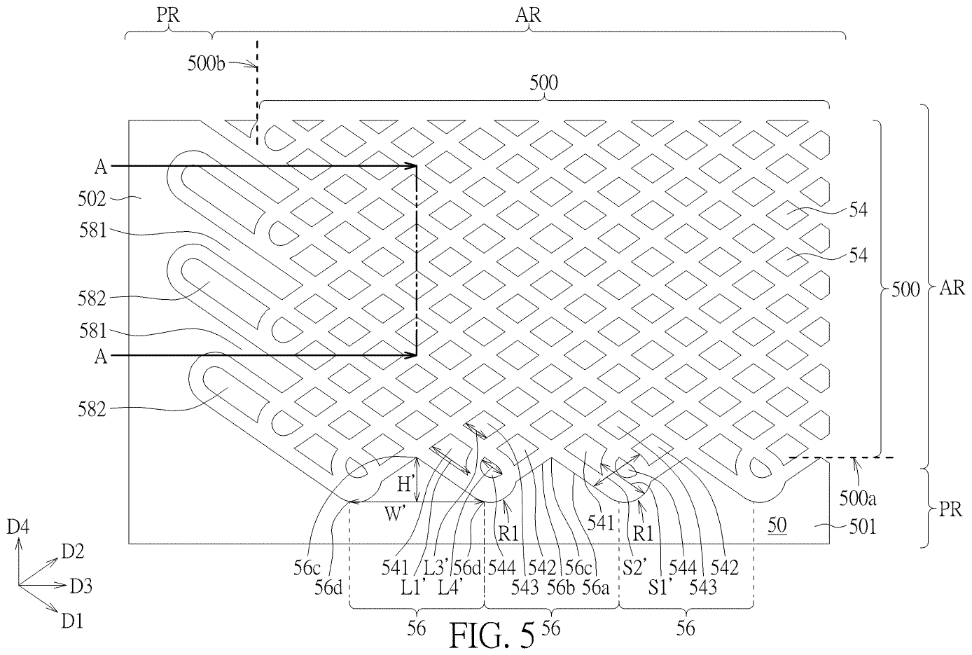

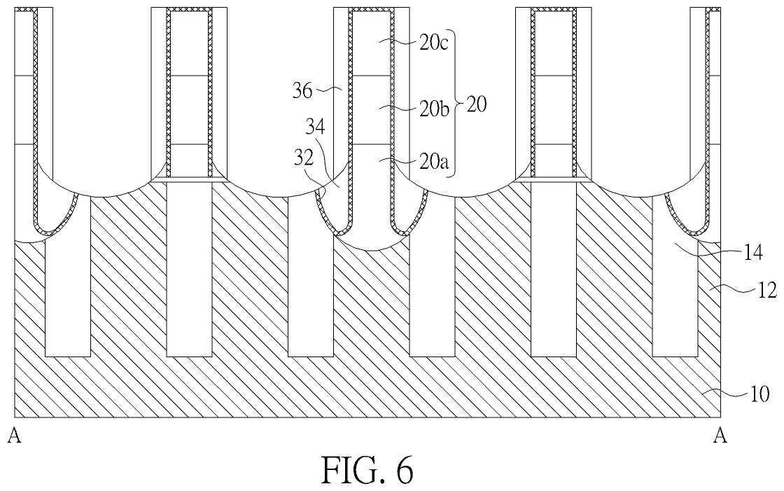

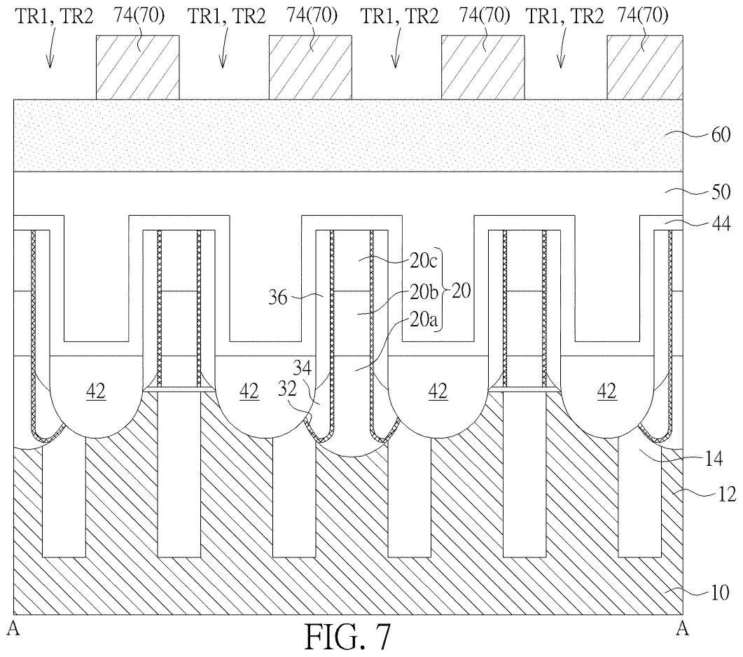

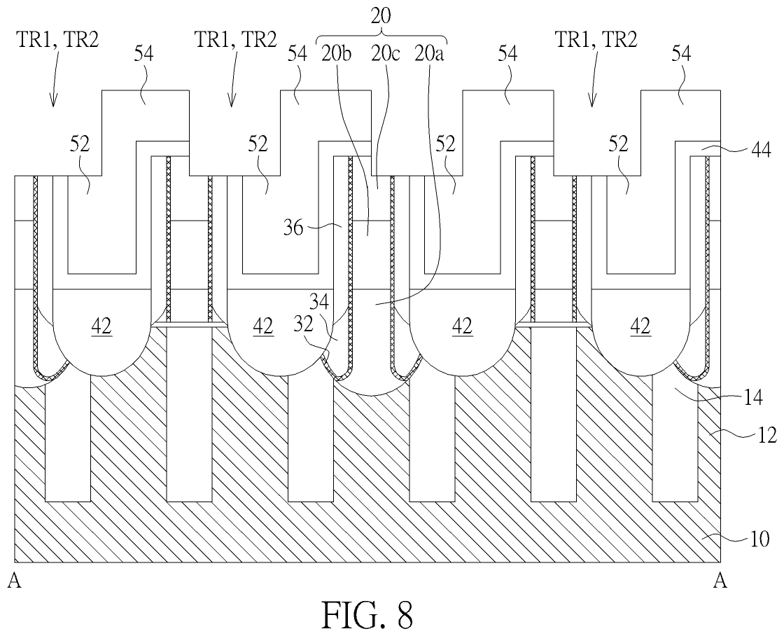

FIG. 1 to FIG. 8 are schematic drawings illustrating intermediates of a semiconductor structure in a manufacturing process according to an embodiment of the present invention. FIG. 1 to FIG. 5 are plan views. FIG. 6 is a cross-sectional view along the line AA as illustrated in FIG. 1. FIG. 7 is a cross-sectional view along the line AA as illustrated in FIG. 3. FIG. 8 is a cross-sectional view along the line AA as illustrated in FIG. 5. The line AA substantially extends along the fourth direction D4.

The semiconductor structure provided by the present invention may be utilized to fabricate dynamic random access memory (DRAM) with stacked capacitors. The semiconductor structure of the present invention may also be utilized to manufacture other types of semiconductor devices without departing from the scope of the present invention.

Please refer to FIG. 1 and FIG. 6. A substrate 10 is provided. The substrate 10 may be, for example, a silicon substrate, an epitaxial silicon substrate, a silicon germanium substrate, a silicon carbide substrate, or a silicon-on-insulator (SOI) substrate, but is not limited thereto. A cell region AR and a peripheral region PR are defined on the substrate 10. The cell region AR may also be referred to as an array region, which is the region where the memory cells are formed. The memory cells may be dynamic random access memory cells. The peripheral region PR is adjacent to the outer side of the cell region AR, serving to separate the cell region AR from other circuit regions on the substrate 10. According to an embodiment of the present invention, the peripheral region PR may include various peripheral circuits, such as drivers, buffers, amplifiers, and decoders, but is not limited thereto. In some embodiments, the peripheral region PR is also the region where the peripheral circuits are electrically connected to the word lines and the bit lines to control operations of the memory cells. Isolation structures 14 are formed in the substrate 10 to define a plurality of active regions 12 in the cell region AR. The active regions 12 respectively extend lengthwise along the first direction D1, and are parallel and staggered to each other to form an array. In some embodiments, the active regions 12 may extend and arranged along other direction according to design requirements. In some embodiments, a peripheral structure 120 that extends along the boundary between the peripheral region PR and the cell region AR may be defined in the peripheral region PR by the isolation structures 14.

A plurality of word line structures 16 are disposed in the substrate 10, extending along the fourth direction D4 and arranged in parallel along the third direction D3 to intersect the active regions 12 and the isolation structures 14, so as to divide each of the active regions 12 into two end portions and a middle portion. The portions of the word line structures 16 that intersect the active regions 12 serve as the control gates for the transistors of the memory cells. The portions of the word line structures 16 that intersect the isolation structures 14 serve as passing gates.

A plurality of bit line structures 20 are disposed on the substrate 10, extending along the third direction D3 and arranged in parallel along the fourth direction D4. The bit line structures 20 may include multiple layers, including a semiconductor layer 20a, a metal layer 20b, and a mask layer 20c. Spacers are formed on sidewalls of the bit line structures 20 to provide protection and electrically isolate the bit line structures 20 from the semiconductor layers 42 and the plug structures 52 (as shown in FIG. 8) formed in subsequent process. The spacers may include multiple layers, such as a first spacer 32, a second spacer 34 and a third spacer 36.

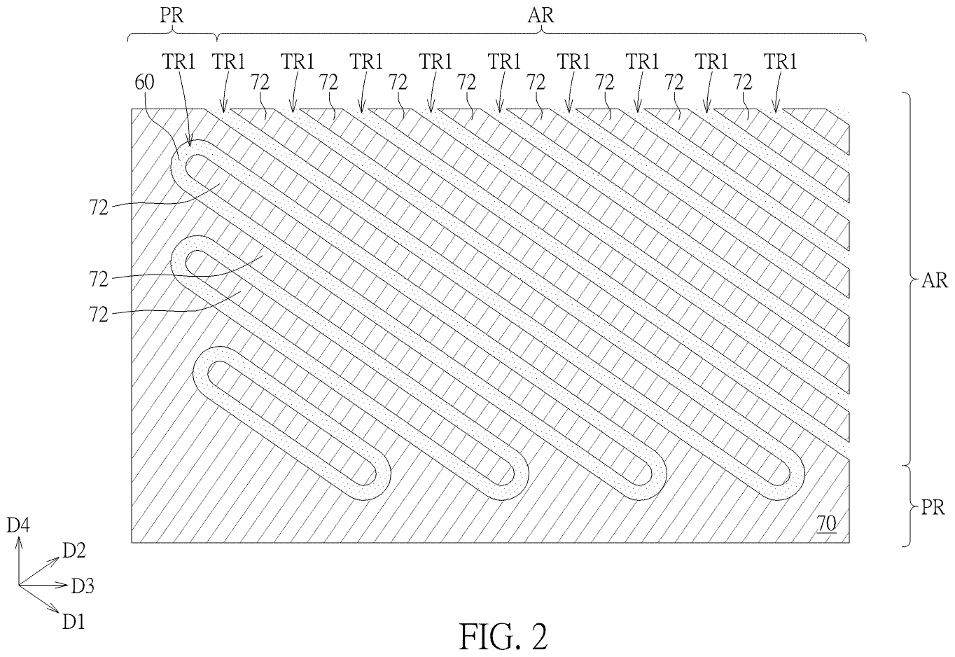

Please refer to FIG. 2, FIG. 3 and FIG. 7. Subsequently, a dielectric layer (not shown) is formed on the substrate 10, filling the spaces between the bit line structures 20. A portion of the dielectric layer is then removed to form a plurality of contact holes (not shown) between the bit line structures 20. The contact holes are separated from each other by the remaining dielectric layer and expose the end portions of the active regions 12. After that, a semiconductor layer 42 is formed in the bottom of the contact holes, after which a barrier layer 44 and a conductive material layer 50 are successively formed on the semiconductor layer 42, filling each of the contact holes. The surface of the conductive material layer 50 is then planarized, and a first mask layer 60 and a second mask layer 70 are sequentially formed on the conductive material layer 50. Subsequently, a first self-aligned double patterning (SADP) process is performed to form a plurality of elongated first ring-shaped trenches TR1 in the second mask layer 70, with their long axes extending along the first direction D1 and parallel to each other, so as to define a plurality of line patterns 72 in the second mask layer 70, which also extend along the first direction D1 and are parallel to each other.

Subsequently, a second self-aligned double patterning process is conducted to form a plurality of elongated second ring-shaped trenches TR2 in the second mask layer 70, with their long axes extending along the second direction D2 and parallel to each other. The second ring-shaped trenches TR2 intersect with the first ring-shaped trenches TR1, dividing the line patterns 72 into a plurality of pad patterns 74, thereby forming a pad array pattern 700 along with a peripheral pattern that at least partially surrounds the pad array pattern 700 in the second mask layer 70.The configuration of the peripheral pattern is determined by the intersection angles and the lengths of the ends of the first ring-shaped trenches TR1 and the second ring-shaped trenches TR2. As illustrated in FIG. 3 of this application, the peripheral pattern includes a first peripheral pattern 701 disposed on a first side 700a of the pad array pattern 700 and including a plurality of triangular protrusions 76 that respectively include a curved edge and are arranged continuously along the third direction D3. The triangular protrusions 76 respectively include a first inclined edge 76a, a second inclined edge 76b, a vertex point 76c, and two bottom points 76d. The first inclined edges 76a substantially extends along the first direction D1. The second inclined edge 76b substantially extends along the second direction D2. The first inclined edge 76a and the second inclined edge 76b join at the vertex point 76c and the bottom points 76d. According to an embodiment of the present invention, as shown in FIG. 3, the first inclined edge 76a is a flat edge. The portion of the second inclined edge 76b adjacent to the bottom point 76d is curved, including a concave profile R1 defined by the end of the first ring-shaped trench TR1. In this embodiment, the concave profile R1 is arc-shaped.

The ratio of the width to and the height of each triangular protrusion 76 is determined by the angle between the first direction D1 and the second direction D2. In this disclosure, the bottom width W of the triangular protrusions 76 is defined as the distance between the two bottom points 76d. The height H of the triangular protrusions 76 is defined as the distance from the vertex point 76c to the virtual straight line connecting one bottom point 76d to the other bottom point 76d. According to an embodiment of the present invention, the bottom width W of each triangular protrusion 76 is greater than the height H.

The portion of the pad array pattern 700 that is adjacent to the first peripheral pattern 701 and between two neighboring triangular protrusions 76 includes a first pad pattern 741, a second pad pattern 742, a third pad pattern 743, and a fourth pad pattern 744. Specifically, the first pad pattern 741 is the pad closest to the first inclined edge 76a along the second direction D2. The second pad pattern 742 is the pad closest to the second inclined edge 76b along the first direction D1. The third pad pattern 743 is disposed on a side of the first pad pattern 741 and the second pad pattern 742 away from the first peripheral pattern 701. The fourth pad pattern 744 is disposed between the first pad pattern 741 and the second inclined edge 76b, aligned with the first pad pattern 741 along the first direction D1. The fourth pad pattern 744 is also between the second pad pattern 742 and the first inclined edge 76a and aligned with the second pad pattern 742 along the second direction D2.

According to an embodiment of the present invention, the maximum length L1 of the first pad pattern 741 along the first direction D1 is greater than the maximum length L3 of the third pad pattern 743 along the first direction D1.

According to an embodiment of the present invention, the maximum length L4 of the fourth pad pattern 744 along the first direction D1 is smaller than the maximum length L3 of the third pad pattern 743 along the first direction D1.

According to an embodiment of the present invention, an area of the first pad pattern 741 is larger than an area of the third pad 743.

According to an embodiment of the present invention, an area of the third pad pattern 743 is larger than an area of the fourth pad pattern 744.

According to an embodiment of the present invention, the maximum spacing S1 between the first pad pattern 741 and the concave profile R1 of the second inclined edge 76b along the first direction D1 is greater than the maximum spacing S2 between the second pad pattern 742 and the first inclined edge 76a along the second direction D2.

According to an embodiment of the present invention, as illustrated in FIG. 3, the peripheral pattern further includes a second peripheral pattern 702 disposed on a second side 700b of the pad array pattern 700 along the fourth direction D4, and a plurality of first branch patterns 781 and second branch patterns 782 that respectively extend along the first direction D1 and are alternately arranged along the fourth direction D4 between the second peripheral pattern 702 and the pad array pattern 700. The second peripheral pattern 702 is structurally connected to the first peripheral pattern 701. The first branch patterns 781 are structurally connected to the second peripheral pattern 702, and the second branch patterns 782 are structurally separated from the second peripheral pattern 702.

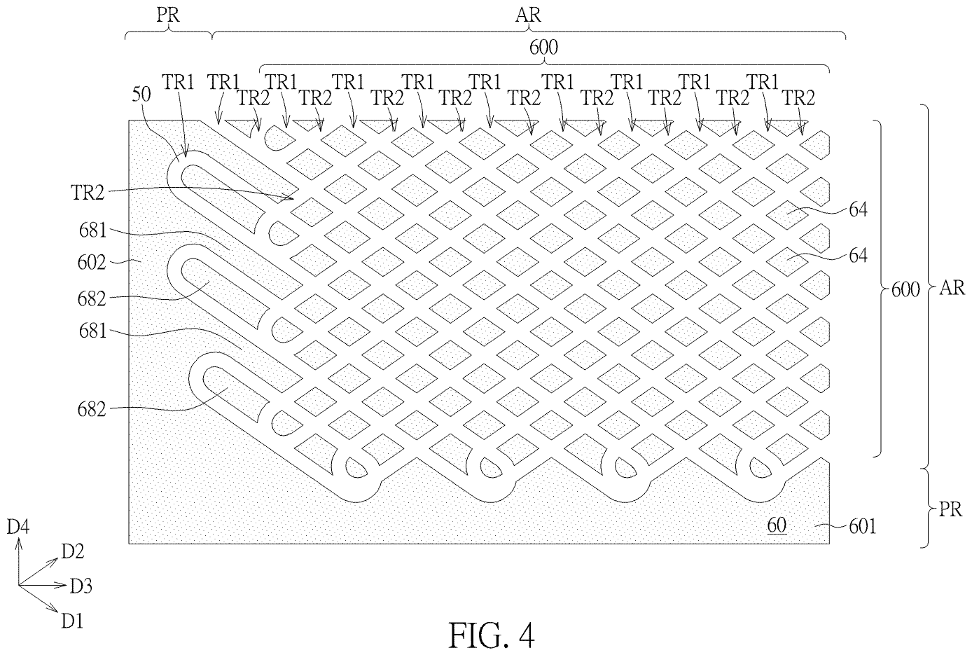

Please refer to FIG. 4. Subsequently, using the patterned second mask layer 70 as an etching mask, a first etching process is performed to etch the first mask layer 60 to transfer the patterns of the first ring-shaped trenches TR1, the second ring-shaped trenches TR2, the pad array pattern 700 and the peripheral pattern to the first mask layer 60. As a result, a pad array pattern 600 is obtained, which includes a plurality of pad patterns 64, a first peripheral pattern 601, a second peripheral pattern 602, a plurality of first branch patterns 681, and a plurality of second branch patterns 682.

Please refer to FIG. 5 and FIG. 8. Subsequently, the patterned first mask 60 is used as an etching mask to perform a second etching process to etch the conductive material layer 50, to transfer the patterns of the first ring-shaped trenches TR1, the second ring-shaped trenches TR2, the pad array pattern 600, the first peripheral pattern 601, the second peripheral pattern 602, the first branch patterns 681, and the second branch patterns 682 to the conductive material layer 50, resulting in a patterned conductive material layer 50.

At this stage of the process, the semiconductor structure of the present invention is obtained, which may be utilized to manufacture stacked capacitor dynamic random access memory (DRAM). The capacitor structures (not shown) are disposed on the pad array 500 and are electrically connected to the transistors in the substrate 10 through the storage node pads 54 and the plug structures 52. The design of the boundary pad and the adjacent portion of the pad array as illustrated in the present invention may improve issues such as peeling or collapse of capacitor structures in the peripheral region, thereby enhancing the reliability of the device formed from the semiconductor structure.

In detail, as illustrated in FIG. 5 and FIG. 8, the semiconductor structure of the present invention includes a substrate 10, a pad array 500 disposed on the substrate 10, and a boundary pad that at least partially surrounds one side of the pad array 500. The pad array 500 includes a plurality of separated storage node pads 54 arranged along a first direction D1 and a second direction D2. The portions of the conductive material layer 50 disposed between the bit line structures 20 are referred to as plug structures 52. The plug structures 52 and the storage node pads 54 are integrally formed. The boundary pad includes a first boundary pad 501 disposed on a first side 500a of the pad array 500. The first boundary pad 501 includes a plurality of triangular protrusions 56 arranged continuously along a third direction D3. Each triangular protrusion 56 has a first inclined edge 56a, a second inclined edge 56b, a vertex point 56c, and two bottom points 56d. The first inclined edge 56a substantially extends along the first direction D1, and the second inclined edge 56b substantially extends along the second direction D2. The first inclined edge 56a and the second inclined edge 56b join at the vertex point 56c and the bottom points 56d. According to an embodiment of the present invention, the first inclined edge 76a is a flat edge. The portion of the second inclined edge 56b adjacent to the bottom points 56d includes a concave profile R1. According to an embodiment of the present invention, the concave profile R1 is an arc-shaped.

The ratio of the width to the height of each triangular protrusion 56 is determined by the angle between the first direction D1 and the second direction D2. In this disclosure, the bottom width W′ of the triangular protrusions 56 is defined as the distance between the two bottom points 56d, and the height H′ of the triangular protrusions 56 is defined as the distance from the vertex point 56c to the virtual straight line from one bottom point 56d to the other bottom point 56d. According to an embodiment of the present invention, the bottom width W′ of each triangular protrusion 56 is greater than the height H'.

The portion of the pad array 500 that is adjacent to the first boundary pad 501 and between neighboring two of the triangular protrusions 56 includes a first pad 541, a second pad 542, a third pad 543, and a fourth pad 544. Specifically, the first pad 541 is the pad closest to the first inclined edge 56a along the second direction D2. The second pad 542 is the one closest to the second inclined edge 56b along the first direction D1. The third pad 543 is disposed on a side of the first pad 541 and the second pad 542 away from the first boundary pad 501. The fourth pad 544 is disposed between the first pad 541 and the second inclined edge 56b and aligned with the first pad 541 along the first direction D1. The fourth pad 544 is also between the second pad 542 and the first inclined edge 56a and aligned with the second pad 542 along the second direction D2.

According to an embodiment of the present invention, the maximum length L1′ of the first pad 541 along the first direction D1 is greater than the maximum length L3′ of the third pad 543 along the first direction D1.

According to an embodiment of the present invention, the maximum length L4′ of the fourth pad 544 along the first direction D1 is smaller than the maximum length L3′ of the third pad 543 along the first direction D1.

According to an embodiment of the present invention, an area of the first pad 541 is larger than an area of the third pad 543. According to an embodiment of the present invention, an area of the third pad 543 is larger than an area of the fourth pad 544.

According to an embodiment of the present invention, the maximum spacing S1′ between the first pad 541 and the concave profile R1 of the second inclined edge 56b along the first direction D1 is greater than the maximum spacing S2′ between the second pad 542 and the first inclined edge 56a along the second direction D2.

According to an embodiment of the present invention, as shown in FIG. 5, the peripheral pattern further includes a second boundary pad 502 disposed on a second side 500b of the pad array 500 along the fourth direction D4, and a plurality of first branch pads 581 and second branch pads 582 that respectively extend along the first direction D1 and are alternately arranged along the fourth direction D4 between the second boundary pad 502 and the pad array 500. The second boundary pad 502 is structurally connected to the first boundary pad 501. The first branch pads 581 are structurally connected to the second boundary pad 502, and the second branch pads 582 are structurally separated from the second boundary pad 502.

The following text will describe different embodiments of the present invention. For the sake of simplicity, the following description will mainly focus on the differences between each embodiment, without reiterating the similarities. Identical components in each embodiment are marked with the same reference numbers to facilitate comparison between the various embodiments.

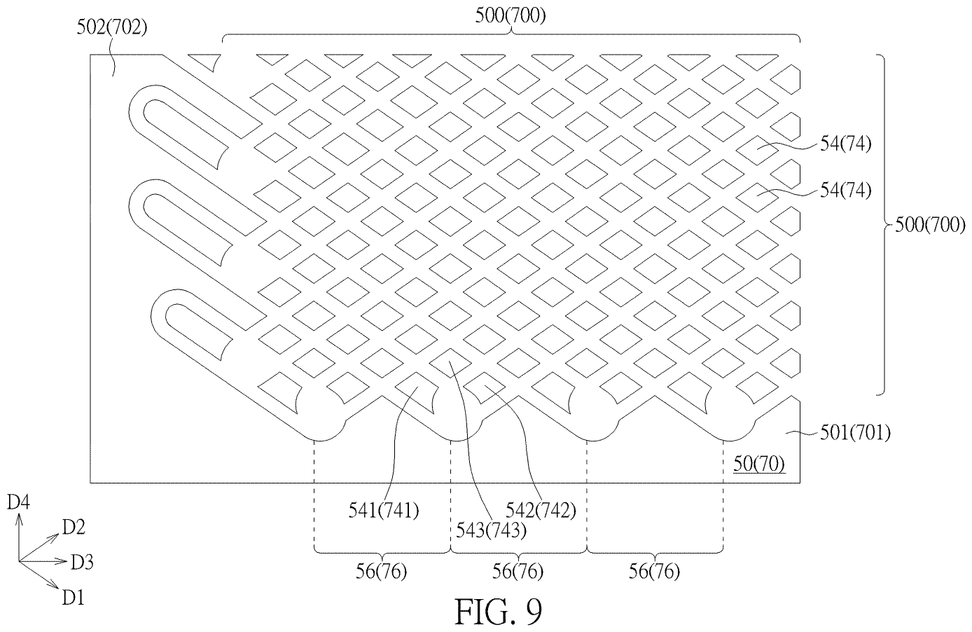

Please refer to FIG. 9, which is a schematic drawing illustrating a plan view of a patterned second mask layer 70 or a patterned conductive material layer 50 of a semiconductor structure according to an embodiment of the present invention. The embodiment depicted in FIG. 9 differs from the embodiment shown in FIG. 3 and FIG. 5 in that the fourth pad patterns 744 are not formed in the second mask layer 70. This may be achieved by adjusting the second self-aligned double patterning process to reduce the end length of the second ring-shaped trenches TR2, rendering the fourth pad patterns 744 too small to be formed in the patterned second mask layer 70. Consequently, after transferring the pattern of the second mask layer 70 to the first mask layer 60 and subsequently to the conductive material layer 50, no fourth pads 544 would be formed in the patterned conductive material layer 50.

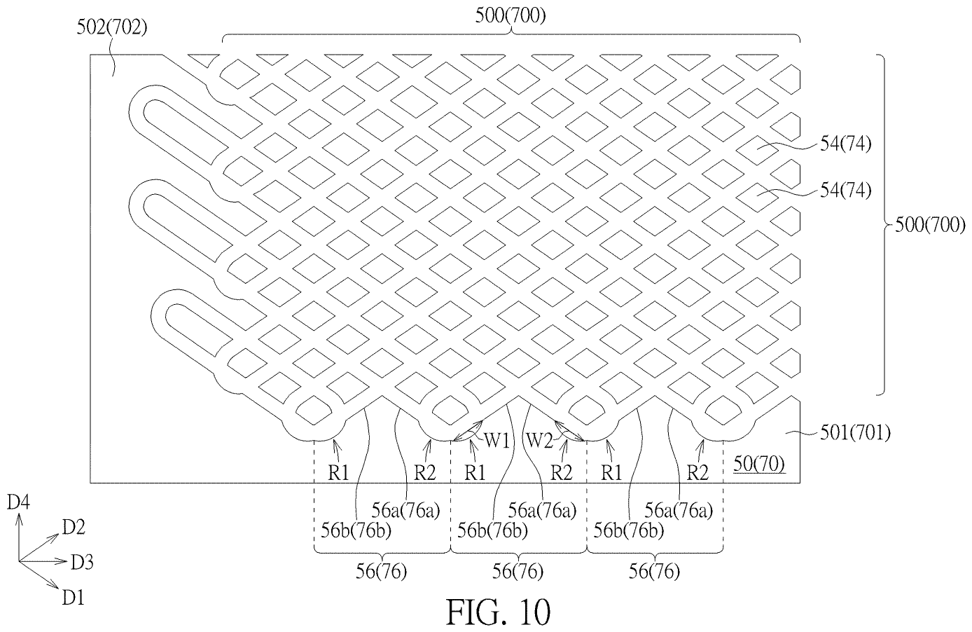

Please refer to FIG. 10, which is a schematic drawing illustrating a plan view of a patterned second mask layer 70 or a patterned conductive material layer 50 of a semiconductor structure according to an embodiment of the present invention. The embodiment depicted in FIG. 10 differs from the embodiment shown in FIG. 3 and FIG. 5 in that the first inclined edges 76a of the triangular protrusions 76 of the first peripheral pattern 701 also have a concave profile R2, respectively. This may be achieved by adjusting the second self-aligned double patterning process to extend the end length of the second ring-shaped trenches TR2, thereby defining a concave profile R2 on each of the first inclined edges 76a of the triangular protrusions 76 of the first peripheral pattern 701. Consequently, after transferring the pattern of the second mask layer 70 to the first mask layer 60 and subsequently to the conductive material layer 50, each of the first inclined edges 56a of the triangular protrusions 56 of the first boundary pad 501 also has a concave profile R2. The width W1 of the concave profile R1 along the second direction D2 and the width W2 of the concave profile R2 along the first direction D1 are determined by the end profiles of the first ring-shaped trench TR1 and the second ring-shaped trench TR2, respectively. According to an embodiment of the present invention, the width W1 and width W2 are different. According to another embodiment of the present invention, the width W1 is equal to the width W2.

In conclusion, the present invention provides a semiconductor structure having a pad array and a boundary pad that at least partially surrounds the pad array. The pad array and the boundary pad are formed by performing a first self-aligned double patterning process and a second self-aligned double patterning process to form a plurality of first ring-shaped trenches TR1 and a plurality of second ring-shaped trenches TR2 that intersect to define the patterns of the pad array and the boundary pad. The configuration of the boundary pad and the layout of the pad array may be adjusted to match the arrangement of the capacitor structures in the peripheral region by adjusting the lengths of the first ring-shaped trenches TR1 and the second ring-shaped trenches TR2 as well as the intersecting angles. In this way, problems such as peeling or collapse of capacitor structures in the peripheral region may be improved, and device reliability may be enhanced.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A semiconductor structure, comprising:
a pad array, comprising a plurality of storage node pads arranged along a first direction and a second direction; and
a first boundary pad, comprising a plurality of triangular protrusions that are arranged continuously along a third direction and disposed on a first side of the pad array, wherein each of the triangular protrusions has a vertex point and a first inclined edge and a second inclined edge that join at the vertex point, wherein the second inclined edge comprises a first concave profile.

2. The semiconductor structure according to claim 1, wherein a bottom width of each of the triangular protrusions is greater than a height of each of the triangular protrusions.

3. The semiconductor structure according to claim 1, wherein the first inclined edge extends along the first direction, and the second inclined edge extends along the second direction.

4. The semiconductor structure according to claim 1, wherein the plurality of storage node pads comprise:
a first pad that is closest to the first inclined edge along the second direction;
a second pad that is closest to the second inclined edge along the first direction; and
a third pad on a side of the first pad and the second pad away from the first boundary pad, wherein the third pad is aligned with the first pad along the second direction and aligned with the second pad along the first direction, wherein a maximum length of the first pad along the first direction is greater than a maximum length of the third pad along the first direction.

5. The semiconductor structure according to claim 4, wherein an area of the first pad is larger than an area of the third pad.

6. The semiconductor structure according to claim 4, wherein the first inclined edge is a flat edge, and a maximum spacing between the first pad and the first concave profile of the second inclined edge along the first direction is greater than a maximum spacing between the second pad and the first inclined edge along the second direction.

7. The semiconductor structure according to claim 1, wherein the first inclined edge comprises a second concave profile.

8. The semiconductor structure according to claim 7, wherein a width of the second concave profile of the first inclined edge and a width of the first concave profile of the second inclined edge are different.

9. The semiconductor structure according to claim 7, wherein the plurality of storage node pads comprise:
a first pad that is closest to the first inclined edge along the second direction;
a second pad that is closest to the second inclined edge along the first direction;
a third pad disposed on a side of the first pad and the second pad away from the first boundary pad, wherein the third pad is aligned with the first pad along the second direction and aligned with the second pad along the first direction; and
a fourth pad disposed between the first pad and the second inclined edge and aligned with the first pad along the first direction, and also between the second pad and the first inclined edge and aligned with the second pad along the second direction, wherein a maximum length of the fourth pad along the first direction is smaller than a maximum length of the third pad along the first direction.

10. The semiconductor structure according to claim 9, wherein an area of the third pad is larger than an area of the fourth pad, and an area of the first pad is larger than the area of the third pad.

11. The semiconductor structure according to claim 1, further comprising:
a second boundary pad disposed on a second side of the pad array along a fourth direction, wherein the fourth direction and the third direction are perpendicular; and
a plurality of first branch pads and a plurality of second branch pads, respectively extending along the first direction and alternately arranged along the fourth direction between the second boundary pad and the pad array, wherein the first branch pads are structurally connected to the second boundary pad, the second branch pads are structurally separated from the second boundary pad.

12. A method for forming a semiconductor structure, comprising:
forming a conductive material layer, a first mask layer and a second mask layer successively on a substrate;
performing a first self-aligned double patterning process to form a plurality of first ring-shaped trenches in the second mask layer thereby defining a plurality of line patterns that extend along a first direction and are parallel to each other; and
performing a second self-aligned double patterning process to form a plurality of second ring-shaped trenches in the second mask layer, wherein the second ring-shaped trenches extend along a second direction and intersect the line patterns, thereby obtaining a pad array pattern and a peripheral pattern surrounding the pad array, wherein the peripheral pattern comprises a first peripheral pattern disposed on a first side of the pad array pattern, wherein the first peripheral pattern comprises a plurality of triangular protrusions arranged continuously along a third direction, wherein each of the triangular protrusions has a vertex point and a first inclined edge and a second inclined edge that join at the vertex point, wherein the second inclined edge comprises a first concave profile.

13. The method for forming a semiconductor structure according to claim 12, wherein a bottom width of each of the triangular protrusions is greater than a height of each of the triangular protrusions.

14. The method for forming a semiconductor structure according to claim 12, wherein the first inclined edge extends along the first direction, the second inclined edge extends along the second direction.

15. The method for forming a semiconductor structure according to claim 12, wherein the pad array pattern comprises:
a first pad pattern that is closest to the first inclined edge along the second direction;
a second pad pattern that is closest to the second inclined edge along the first direction; and
a third pad pattern on a side of the first pad pattern and the second pad pattern away from the first peripheral pattern, wherein the third pad pattern is aligned with the first pad pattern along the second direction and aligned with the second pad pattern along the first direction, wherein a maximum length of the first pad pattern along the first direction is greater than a maximum length of the third pad pattern along the first direction.

16. The method for forming a semiconductor structure according to claim 15, wherein the first inclined edge is a flat edge, a maximum spacing between the first pad pattern and the first concave profile of the second inclined edge along the first direction is greater than a maximum spacing between the second pad pattern and the first inclined edge along the second direction.

17. The method for forming a semiconductor structure according to claim 12, wherein the first inclined edge comprises a second concave profile.

18. The method for forming a semiconductor structure according to claim 17, wherein a width of the second concave profile of the first inclined edge and a width of the first concave profile of the second inclined edge are different.

19. The method for forming a semiconductor structure according to claim 17, wherein the pad array pattern comprises:
a first pad pattern that is closest to the first inclined edge along the second direction;
a second pad pattern that is closest to the second inclined edge along the first direction;
a third pad pattern disposed on a side of the first pad pattern and the second pad pattern away from the first peripheral pattern, wherein the third pad pattern is aligned with the first pad pattern along the second direction and aligned with the second pad pattern along the first direction; and
a fourth pad pattern disposed between the first pad pattern and the second inclined edge and aligned with the first pad pattern along the first direction, and also between the second pad pattern and the first inclined edge and aligned with the second pad pattern along the second direction, wherein a maximum length of the fourth pad pattern along the first direction is smaller than a maximum length of the third pad pattern along the first direction.

20. The method for forming a semiconductor structure according to claim 12, wherein the peripheral pattern further comprises:
a second peripheral pattern disposed on a second side of the pad array pattern along a fourth direction, wherein the fourth direction and the third direction are perpendicular; and
a plurality of first branch patterns and a plurality of second branch patterns, respectively extending along the first direction and alternately arranged along the fourth direction between the second peripheral pattern and the pad array pattern, wherein the first branch patterns are structurally connected to the second peripheral pattern, and the second branch patterns are structurally separated from the second peripheral pattern.

21. The method for forming a semiconductor structure according to claim 12, further comprising:
performing a first etching process using the second mask layer as an etching mask to transfer the pad array pattern and the peripheral pattern to the first mask layer; and
performing a second etching process using the first mask layer as an etching mask to transfer the pad array pattern and the peripheral pattern to the conductive material layer, thereby obtaining a pad array and a boundary pad surrounding the pad array.
